(19) United States
(12) Patent Application Publication
(10) Pub. No.: US 2003/0001262 A1
(43) Pub. Date: Jan. 2, 2003

(54) Semiconductor device having solder bumps and method for manufacturing same

(76) Inventor: Harumi Mizunashi, Tokyo (JP)

Correspondence Address: Sughrue Mion Zinn MacPeak & Seas, 2100 Pennsylvania Avenue, Washington, DC, 20037, US

(21) Appl. No.: 09/578,925

(22) Filed: May 26, 2000

(30) Foreign Application Priority Data
May 27, 1999 (JP) 11-147752

(51) Int. Cl. H01L 21/44; H01L 23/48; H01L 29/40

(52) U.S. Cl. 257/737; 257/678; 438/613

(57) ABSTRACT

A semiconductor device including: a circuit board having a plurality of first electrodes thereon: a semiconductor chip having a plurality of second electrodes thereon: a bonding sheet sandwiched between said circuit boar and said semiconductor chip and having a plurality of apertures; and a solder bump disposed in each of apertures for connecting a corresponding one of the first electrodes and a corresponding one of the second electrodes. The semiconductor device can be manufactured without a conventional resin-applying step, thereby removing the cost for conducting the step. Also a short-circuit failure can be effectively prevented because the solder bumps are securely maintained in the apertures.

### BACKGROUND OF THE INVENTION

(a) Field of the Invention

The present invention relates to a semiconductor device and a method for manufacturing the same, more in detail to the semiconductor device including a circuit board mounting thereon a semiconductor chip by using solder bumps and the method for manufacturing the same.

(b) Description of the Related Art

A flip chip ball grid array (FCBGA) process is known as a packaging technique suitable for high-density mounting of a large-scale semiconductor integrated circuit (LSI). In the FCBGA process, the LSI is electrically and mechanically bonded to a circuit board of the package side by fixing solder balls having a higher melting point onto a plurality of electrode pads on the LSI and directly connecting the solder balls to respective electrodes of the circuit board.

In a conventional method of manufacturing a semiconductor device in accordance with the FCBGA process shown in FIGS. 1A and 1B, solder balls 25 are fixed onto the surface of an LSI (semiconductor chip) 21 corresponding to a plurality of electrode pads (not shown) before mounting (FIG. 1A). Then, the fixed solder balls 25 of the LSI 21 are connected to respective electrodes in a mounting pad of a circuit board 24 for the FCBGA process as shown in FIG. 1A.

There are problems in the FCBGA process that cracks are likely to be generated at portions connected by the solder due to a tensile stress generated by a difference in thermal expansion between the LSI 21 and the circuit board 24, and that insufficient insulation resistance between electrodes is likely to occur due to a small space between electrodes, which are subjected to ingress of small conductive foreign substances and may have deficiencies such as deformation, protrusion and mixing of solder waste. In order to solve the problems, underfill resin 23 is applied to the space between the LSI 21 and the circuit board 24 for curing as shown in FIG. 1B.

In the resin insulation method, addition of the steps of applying and curing the underfill resin 23 increases the manufacturing cost. In addition, voids may be generated in the underfill resin 23 to protrude the solder, thereby short-circuiting the adjacent electrodes. Thus, the inspection of the voids is separately required, which also increases the manufacturing cost.

### SUMMARY OF THE INVENTION

In view of the foregoing, an object of the present invention is to provide a semiconductor device and a method for manufacturing the same capable of reducing the manufacturing cost, and suppressing a short-circuit failure between electrodes without using insulation resin.

The present invention provides, in a first aspect thereof, a semiconductor device including: a circuit board having a plurality of first electrodes thereon: a semiconductor chip having a plurality of second electrodes thereon corresponding to the first electrodes: a bonding sheet sandwiched between the circuit board and the semiconductor chip and having a plurality of apertures corresponding to the first and second electrodes; and a solder bump disposed in each of the apertures for connecting a corresponding one of the first electrodes and a corresponding one of the second electrodes.

The present invention provides, in a second aspect thereof, a method for manufacturing a semiconductor device including the steps of: forming a solder bump on each of first electrodes of a semiconductor chip or on each of second electrodes of a semiconductor chip, first electrodes being disposed corresponding to the second electrodes; sandwiching between a circuit board and the semiconductor chip a bonding sheet having a plurality of apertures corresponding to the first and second electrodes so that the apertures receive the respective solder bumps; and melting the solder bumps for electrically connecting the first electrodes and the respective second electrodes through the solder bumps.

In accordance with the first and the second aspects of the present invention, the semiconductor device can be manufactured without a conventional step of applying resin between the semiconductor chip and the circuit board, because the solder bumps are engaged in apertures of the bonding sheet located between the semiconductor chip and the circuit board, thereby removing the cost for conducting the step Also a short-circuit failure between the electrodes can be effectively prevented because the solder bumps are securely maintained in the apertures and are surround by the bonding sheet in which a void is hardly generated.

The above and other objects, features and advantages of the present invention will be more apparent from the following description.

### BRIEF DESCRIPTION OF DRAWINGS

FIGS. 1A and 1B are vertical sectional views consecutively showing respective steps of manufacturing a conventional semiconductor device in accordance with an FCBGA process.

FIG. 2 is a vertical cross-sectional view of a circuit board used in an embodiment of the present invention.

FIG. 3 is a vertical sectional view of an LSI used in the embodiment.

FIG. 4 is a vertical sectional view showing a semiconductor device manufactured by bonding the circuit board of FIG. 2 and the LSI of FIG. 3 in accordance with the embodiment.

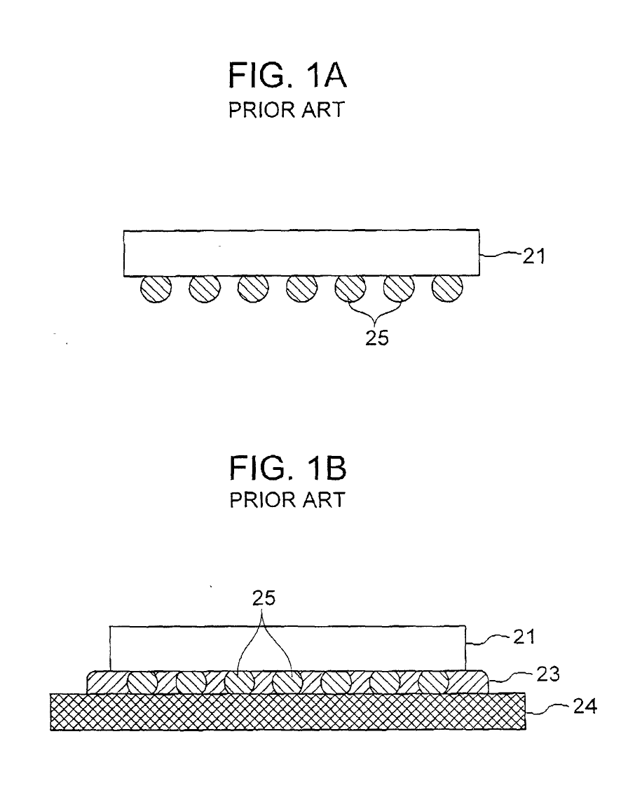

### PREFERRED EMBODIMENTS OF THE INVENTION

Now, the present invention is more specifically described with reference to accompanying drawings.

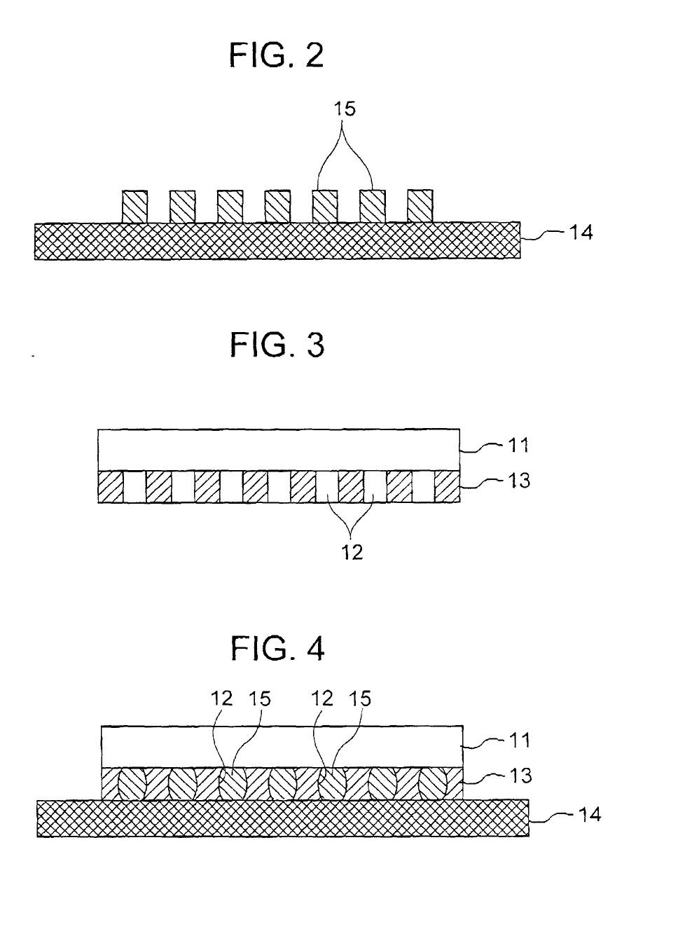

As shown in FIG. 2, a plurality of column-shaped solder bumps 15 having a height of, for example, about 100 to 120 μm are formed on electrodes (not shown) of mounting pads of a circuit board 14. In the column-shaped solder bump 15, the strength thereof against the stress increases and the distance between the adjacent solder bumps 15 can be larger.

In an exemplified configuration, the thickness of the LSI 11 is set at about 700 μm, with the thickness of the circuit board 14 about 1.2 mm, the pitch of the solder bumps about 240 μm, the number of the solder bumps about 3000, and the gap between the LSI 11 and the circuit board 14 after the mounting about 100 μm. The gap is preferably set at about 100 to 90% of the height of the column-shaped solder bump 15.

In addition, the plane view dimensions of the LSI 11, the portion in contact with the solder (surface wetted by solder) on the LSI 11 side and the portion in contact with the solder on the circuit board 14 side may be set at about 13.64 mm×13.64 mm, about 130 μm×130 μm and about 130 μm×130 μm, respectively.

The whole solder bump 15 may be formed by high melting-point solder. The high melting-point solder is used if the LSI 11 can withstand a temperature as high as the melting point of the solder, which reduces the cost because the use of expensive eutectic solder is unnecessary. The solder bump 15 having a two-layer structure may be used in which the circuit board side (fixed end side) of the column shape is formed by the high melting-point solder and the LSI side (free end side) is formed by the eutectic solder. In this case, a working temperature of about 220 to 240° C. is sufficient, and the connection treatment can be conducted at a lower temperature than in the case of using the high melting-point solder in the LSI side.

The eutectic solder is made of a brazing metal having a lower melting point of 183° C., and the working temperature thereof is about 220 to 240° C. The high melting-point solder is made of brazing metals having a melting point (liquidus) higher than the working temperature of the brazing metal having the lower melting point, and contains about 95% of palladium. The melting point thereof is 317° C. and the working temperature is 330 to 350° C.

The solder bump 15 on the circuit board can be formed by disposing the solder bump on a jig and transferring the solder bump onto the circuit board, or by a plating. When the jig is used for forming the column-shaped solder bump, the arrangement of the solder bump is somewhat difficult. When the plating is used, a significant number of solder bumps can be prepared at a time.

As shown in FIG. 3, a bonding sheet (insulation sheet) 13 is affixed onto the surface of the LSI 11. The bonding sheet 13 may be made of thermoplastic polyimide resin, and the bonding sheet 13 is free from voids such as formed in the underfill resin applied to the space between the circuit board and the LSI in the prior art. The bonding sheet 13 has a plurality of cylindrical apertures (engagement apertures) 12 which can receive the solder bumps 15 at corresponding portions of electrode pads (not shown). The cylindrical aperture has a depth same as or similar to the height of the solder bump 15.

As shown in FIG. 4, the circuit board 14 and the LSI 11 are pressed against each other while the respective solder bumps 15 are engaged in the corresponding cylindrical apertures 12. This LSI 11 is mounted on the circuit board 14 after the solder bumps 15 are thermally melted to be connected to electrode pads on the LSI 11. The thermally melting treatment is conducted at about 220 to 240° C., and the bonding sheet 13 is softened and deformed while keeping the stickiness. Accompanied thereby, the respective central portions of the solder bumps 15 outwardly expand to increase the diameters of the respective central portions of the cylindrical apertures 12 so that the solder bumps 15 are not pulled out from the apertures 12.

In the present embodiment, a sufficient amount of solder exits as the solder bumps 15 on the circuit board 14 side, and no preparatory solder is necessary on the LSI 11 side. A small amount of solder may be welded or plated in advance as the preparatory solder, if necessary, on the portions connected by the solder for improving the wettability of the solder and increasing the volume of the solder at the time of the bonding.

Since the solder bump 15 inserted into the cylindrical aperture 12 in the bonding sheet 13 is bonded to the LSI 11, the solder bump 15 is not excessively deformed, and the resin for insulation is unnecessary. The bonding sheet 13 existing between the LSI 11 and the respective electrodes of the pad and between adjacent solder bumps effectively prevents a short-circuit failure.

In the present embodiment, the solder bump 15 is mounted on the circuit board 14 and the bonding sheet 13 is mounted on the LSI 11. However, it may be reversed: the solder bump 15 may be mounted on the LSI 11 with the bonding sheet 13 mounted on the circuit board 14.

Since the above embodiments are described only for examples, the present invention is not limited to the above embodiments and various modifications or alternations can be easily made therefrom by those skilled in the art without departing from the scope of the present invention.

What is claimed is:

1. A semiconductor device comprising:
a circuit board having a plurality of first electrodes thereon:
a semiconductor chip having a plurality of second electrodes thereon corresponding to said first electrodes:
a bonding sheet sandwiched between said circuit boar and said semiconductor chip and having a plurality of apertures corresponding to said first and second electrodes; and
a solder bump disposed in each of said apertures for connecting a corresponding one of said first electrodes and a corresponding one of said second electrodes.

2. The semiconductor device as defined in claim 1, wherein said solder bump has substantially a barrel shape.

3. The semiconductor device as defined in claim 1, wherein said solder bump is made by plating onto either of one of said first electrodes and one of said second electrodes.

4. The semiconductor device as defined in claim 1, wherein said solder bump has a two-layer structure including an first layer and a second layer having melting point higher than a high-melting point of said first layer.

5. The semiconductor device as defined in claim 1, wherein said first layer includes eutectic solder.

6. The semiconductor device as defined in claim 1, wherein said first layer is disposed near said semiconductor chip.

7. A method for manufacturing a semiconductor device comprising the steps of:
forming a solder bump on each of first electrodes of a semiconductor chip or on each of second electrodes of a semiconductor chip, first electrodes being disposed corresponding to the second electrodes;
sandwiching between a circuit board and said semiconductor chip a bonding sheet having a plurality of apertures corresponding to said first and second electrodes so that said apertures receive respective said solder bumps; and
melting said solder bumps for electrically connecting said first electrodes and respective said second electrodes through said solder bumps.

8. The method as defined in claim 7, wherein the solder bump has a cylindrical shape.
